(19) United States
(12) Patent Application Publication
(10) Pub. No.: US 2006/0237735 A1
(43) Pub. Date: Oct. 26, 2006

(54) High-efficiency light extraction structures and methods for solid-state lighting

(76) Inventors: Jean-Yves Naulin, Albany, CA (US); Cheng-Tsin Lee, Richmond, CA (US); Ho-Shang Lee, El Sobrante, CA (US)

Correspondence Address: PARSONS HSUE & DE RUNTZ LLP, 595 MARKET STREET, SUITE 1900, SAN FRANCISCO, CA, 94105, US

(21) Appl. No.: 11/112,641

(22) Filed: Apr. 22, 2005

(51) Int. Cl. H01L 33/00

(52) U.S. Cl. 257/98

(57) ABSTRACT

A soft solder flowing into the recesses of a semiconductor thin film LED provides: (a) increased bonding strength and better mechanical durability, (b) improved heat dissipation, (c) enhanced light extraction when the LED film is bonded to a new carrier. Annealing localized islands of absorbing metal creates an ohmic contact. Those isolated islands are inter-connected by a layer of a highly reflective metal. This design enables a significant absorption reduction within the LED device and leads to a significant improvement of light extraction. Additionally, the light extraction efficiency of an isotropic light emitting device is improved via surface shaping of the device by a 2D-array of micro-lenses and photonic band gap structure. For manufacturability purpose the making of micron-size lenses of the surface of the chip may preferably be performed as a final step, preferably with optical lithography.

### BACKGROUND OF THE INVENTION

This invention relates in general to light emitting structures, and in particular to high efficiency light emitting structures.

Over the last decade, the advent of solid-state lighting has led to rapid advances in the production of high brightness Light Emitting Diodes (LEDs). LEDs hold the promise for a cost-effective solution for increasing illumination-related energy needs. With advanced LED technology, the energy consumption can be reduced significantly.

LED's performances are dictated by both the internal efficiency of the semiconductor structure and by the light extraction efficiency. With the development of high performance MOCVD (Metal-Organic Chemical Vapor Deposition), liquid phase epitaxial growth tools (LPE) and MBE (Molecular Beam Epitaxy), the internal efficiency of LEDs is approaching 100%. In contrast, the extraction efficiency of LEDs still needs much more improvement.

The extraction efficiency reflects the ability of photons emitted inside the LED chip to escape into the surrounding medium. For example, the index of refraction of Gallium phosphide-based materials is close to 3.4, compared with 1 for air and 1.5 for epoxy. This results in a critical angle of 17° for air and 25° in epoxy, respectively. If a single interface is considered only 2% of the incident light into air and 4% into epoxy will be extracted. As a comparison, the index of refraction of Gallium nitride-based materials is close to 2.3. This results in a critical angle of 26° into air and 41° into epoxy. If a single interface is considered only 5% of the incident light into air and 12% into epoxy will be extracted. The rest is reflected into the semiconductor where it will eventually be reabsorbed or recycled and results in the performance degradation of the device.

Increasing the extraction efficiency of LEDs is one of the popular themes for improving the brightness of LEDs. Methods such as surface texturing, grating thin film (U.S. Pat. No. 5,779,924), modifying chip geometry (U.S. Pat. No. 6,323,063) and photonic crystal structure (U.S. Pat. No. 5,955,749) are implemented.

One proposal for improving the extraction efficiency of LEDs consists of removing the absorbing substrate and replacing it with a reflective mirror. The remaining thin semiconductor film that emits light is too fragile to be a stand-alone device and needs to be supported after removal of its substrate. Given that conventional red (AlGaInP) and blue (InGaN) LED are grown from N+ GaAs and sapphire substrates, respectively, one of the major drawbacks of GaAs and sapphire is their poor thermal conductivity; GaAs and sapphire have a thermal conductivity value of 50, and 40 w/m° K roughly, respectively. Obviously, replacing GaAs or sapphire with a high thermal conductivity carrier such as Si (150 W/m° K) or Cu (400 W/m° K) can significantly improve the LED performance through better heat dissipation. However, these carriers have Coefficients of Thermal Expansion (CTE) that are much larger than that of GaAs or sapphire. Direct bonding of the GaAs or GaN based LED over Si or Cu carrier can result in high stress, which induces cracking of the LED. Wafer bonding techniques had been proposed in U.S. Pat. No. 6,221,683 and U.S. Pat. No. 6,258,699, which use high temperature alloys such as AuSn/Au and AuBe/Au for bonding. These prior devices suffer from high bonding stress and high cost.

Another major challenge for the wafer bonding process is the reduction of the contact metal area without hurting the current spreading. Photon recycling contributes to light extraction efficiency, but require minimum absorbing center in the LED. The internal quantum efficiency for the AlGaInP based LED is close to 100%. The main absorption comes from the contact metal (both P and N contact), which has relatively high absorption. The ohmic contact on the P side for an N-side up LED can be reduced through micro contacts spread evenly over the entire LED surface.

However, a contact pad on the N side of at least 100 microns diameter is required for wire bonding. The large contact pad not only blocks the light but also results in significant degradation of the extraction efficiency of the LED. None of the devices currently used or proposed is entirely satisfactory in regard to the issues described above.

The goal of the present invention is to propose cost-effective and innovative methods to solve these issues.

### SUMMARY OF THE INVENTION

Performance of a light emitting apparatus can be improved by attaching to a semiconductor structure comprising a light emitting diode, a carrier that has a thermal conductivity that is higher than that of the structure may be used, and/or a carrier may be employed where there is a substantial mismatch between CTE of the carrier and that of the structure. In one embodiment, the mismatch between CTE of the carrier and that of the structure is at least 10%. This carrier preferably replaces the growth substrate upon which the semiconductor structure is grown. The structure has recesses therein and a stress-absorbing material attaches the structure to the carrier so that it substantially fills said recesses. This reduces the stress when the semiconductor structure and carrier are attached together preferably in a thermal process despite their different thermal conductivities and/or different CTEs.

To attach a semiconductor wafer to a carrier, a semiconductor wafer and a carrier are brought into contact in a vacuum environment; and substantially uniform pressure and temperature are applied to the semiconductor wafer and the carrier to create a strong and uniform bonding therebetween, wherein the pressure is unidirectional or isostatic.

In an embodiment of yet another aspect of the invention, an electrically conductive network for applying a current to a semiconductor structure comprising a light emitting diode to cause the diode to emit light. The network comprises an array of metal contacts wherein each of at least some of the contacts is not in contact with any other contact in the array, and wherein the contacts form ohmic contacts with the semiconductor structure. An electrically conductive material connects the contacts. Preferably the material is light reflective or substantially transparent with respect to light emitted by the diode.

The above described features may be used individually or in any combination for enhanced performance.

### BRIEF DESCRIPTION OF THE DRAWINGS

FIGS. 1a-1d show examples of discontinuous metal patterns distributed uniformly on the surface of a semiconductor LED structure to illustrate one embodiment of one aspect of the invention.

FIG. 2-a is a top view of an arrangement of a set of parallel recess lines inscribed into a semiconductor structure by dry etching or wet etching or combination of both methods to illustrate one embodiment of another aspect of the invention.

FIG. 2-b is a top view of an arrangement of two orthogonal sets of line recesses.

FIG. 2-c is a cross-sectional view of the structure in FIG. 2-a to illustrate the shape of recesses.

FIG. 2-d is the 3-D perspective view of the structure in FIG. 2-a.

FIGS. 3a-3d are views illustrating a geometrical relation between a light emitting chip, bonding pad and bonding wire in the prior art devices.

FIGS. 3e and 3f are top views of a light emitting diode (LED) chip of two different embodiments where isolated metal islands spread over the LED surface are connected by a conductive network.

FIG. 3g is a cross-sectional view of the diode (LED) chip in FIG. 3e showing the current spreading across the active layer.

FIGS. 4a, 4c are cross-sectional views and FIGS. 4b, 4d are top views of a patterned semiconductor surface with convex (FIGS. 4a, 4b) and concave (FIGS. 4c, 4d) microlenses.

FIG. 5 is a cross-sectional view that shows an epitaxial structure of a light emitting diode on its original growth substrate.

FIG. 6 is a cross-sectional view of a LED structure with recesses and reflective mirrors and is ready for the bonding process of the LED structure to a new carrier.

FIG. 7 is a cross-sectional structure view of a new carrier before bonding.

FIG. 8 is a cross-sectional structural view of a bonded semiconductor film with LED structure on its new carrier after removal of the growth substrate to illustrate one embodiment of one aspect of the invention.

FIG. 9 is a cross-sectional view of a semiconductor film with LED structure shows an example of the new metal pattern associated with shaping of the top surface of the LED to illustrate one embodiment of another aspect of the invention.

FIG. 10 shows a cross-sectional of an isobaric wafer bonding apparatus to illustrate one embodiment of yet another aspect of the invention.

FIGS. 11a to 11c illustrate a photonic band gap structure inscribed onto the surface of the semiconductor layers.

Identical or similar components are identified by the same numerals in this application.

### DETAILED DESCRIPTION OF PREFERRED EMBODIMENTS OF THE INVENTION

One of the major challenges for wafer bonding process is the selection of a cost-effective carrier with high thermal conductivity and CTE match with that of the LED. To reduce the stress caused by the CTE mismatch between LED and carrier, a low temperature bonding process is preferred. Low temperature solders such as In, Sn, Pb/Sn and Au/Sn are preferred to perform the bonding between LED and carrier. The stress generated between the carrier and LED are relatively low due to the low bonding temperature. The stress can be further released by proper heat treatment after bonding. After wafer bonding, the original substrates such as GaAs and sapphire can be removed by etching or laser lift-off process and only a thin film (a few microns thick) LED structure remains on the carrier. The topside (usually N-side) of the LED can be coated with proper N metal (e.g. Au—Ge for N+ GaAs) using e-beam evaporation or sputtering method. In order to reduce the contact resistance between the semiconductor and the N metal, a proper annealing procedure is needed which usually require high temperature such as 360 C in an inert atmosphere such as N2. During the annealing procedure, stress will be generated between thin film LED, bonding material (e.g. solder) and carrier. The LED thin film tends to wrinkle or crack without proper stress management. How to generate a reliable thin film LED device to survive the high temperature annealing procedure is another challenge to the wafer bonding process.

The present invention discloses a bonding method that reduces the stress generated by the CTE mismatch between the thin film semiconductor film, the bonding layer, and the new carrier. This method also increases the bonding strength between the semiconductor film and the new carrier as well as the heat dissipation capabilities of the device. The making of some recesses into the semiconductor film and their filling with higher thermal conductivity, higher CTE material. (e.g. the bonding layer) creates a clamping effect on the semiconductor film. Therefore, the bonding between the semiconductor film and the new carrier is enhanced. As the thermal conductivity of the material filling the recesses is higher than the thermal conductivity of the semiconductor material, the heat dissipation capabilities of such as device will be higher than that of a conventional film without recess patterning. The present invention offers improved bonding strength, better heat dissipation and higher extraction efficiency.

The present invention also discloses a wafer bonding and an N metal annealing method, which utilizes a flexible film to generate vacuum sealing and uniform gas pressure over the LED. By the support of the flexible film, thin film LED device can be maintained flat and crack free after the bonding and annealing procedure. This bonding/annealing method is cost effective for mass production of the thin film LED device.

The present invention also discloses a method to improve the extraction efficiency of LEDs by reducing the absorption due to the electrode formed on the top of the device. The ohmic contact is created by high temperature annealing of localized small islands of absorbing metal. These localized patterns of metal are distributed on the surface of the semiconductor device and connected by a layer of highly reflective metal. The overall absorption of the device is therefore reduced and the extraction efficiency increased.

The present invention also incorporates some regular surface patterning such as Photonic Band Gap structure and micro-lens array onto the semiconductor film to enhance light extraction. This extraction mechanism is further enhanced by a highly reflective mirror at the interface of wafer bonding.

Each of the features described herein can be used individually or in conjunction with the others. The aspects of this invention and its advantages will be better understood by reference to the accompanying detailed description and drawings.

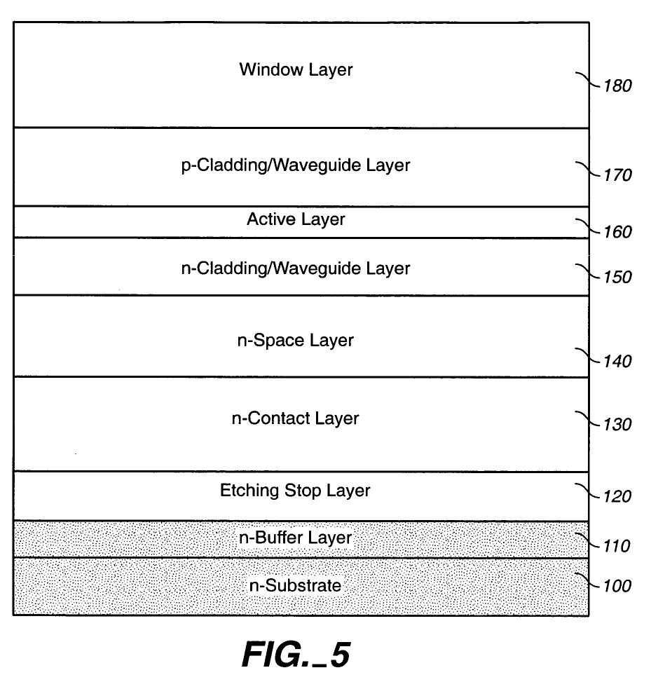

FIG. 5 illustrates a typical epitaxial structure for III-V materials. State of the art Metal-Organic Chemical Vapor Deposition (MOCVD) and Molecular Beam Epitaxy (MBE) allow one to precisely control the properties of the materials as well as growth conditions. Due to the high doping level of the different layers, typically >10¹⁸, the propensity for inter-diffusion in the structure may be very high. This may adversely affect crystalline quality of the epitaxial layers. To achieve better crystalline quality, the n-doped layers are grown first, and then the active layer and p-doped layers are grown sequentially thereafter.

A buffer layer 110 is initially grown on the substrate 100 to ensure good crystalline properties and optimal epitaxial quality of the structure. On top of this layer, an etch-stop layer 120 is deposited. This layer prevents the damage of the LED structure when the substrate is removed. The next layer grown is an n-contact layer 130 followed by a n-space layer 140. The steps that follow include the growing of an n-cladding/waveguide layer 150, an active layer 160 and a p-cladding/waveguide layer 170. The tailoring of the properties of these three layers (thickness, strain, doping, refractive index) will establish the properties of the light emitting structure. Finally, a window layer 180 is grown on the top of the structure to ensure a good current spreading over the whole LED. The thickness of the window layer 180 is in range of one micrometer to tens of micrometers. A contact layer for forming a better ohmic contact with P-contact metal may be added on the top of the window layer 180 as an option.

The substrate of FIG. 5 is either a highly absorbing substrate such as GaAs for AlInGaP LEDs or a poor thermal conductor such as sapphire for AlInGaN films. The substrate 100, GaAs or sapphire, has poor thermal conductivity; GaAs and sapphire have thermal conductivity values of 50, and 40 w/m° K roughly, respectively. Obviously, replacing GaAs or sapphire with a high thermal conductivity carrier such as Si (150 W/m° K) or Cu (400 W/m° K) can significantly improve the LED performance through better heat dissipation.

Therefore, an improved wafer bonding technique is highly desirable and will be introduced in the next section.

Recesses and Composite Reflective Mirror

Direct bonding of the GaAs or GaN based LED to carriers such as Si, Cu/Si or Cu carrier in a thermal process can result in high stress due to high CTE mismatch and cracking of the LED chip. One of the major challenges for wafer bonding process is the selection of a cost-effective carrier with high thermal conductivity and CTE match with that of the LED. To improve the bonding strength and to relax the stress generated during the high temperature bonding process, the semiconductor film comprises patterned recesses which are filled with a high thermal conductivity material.

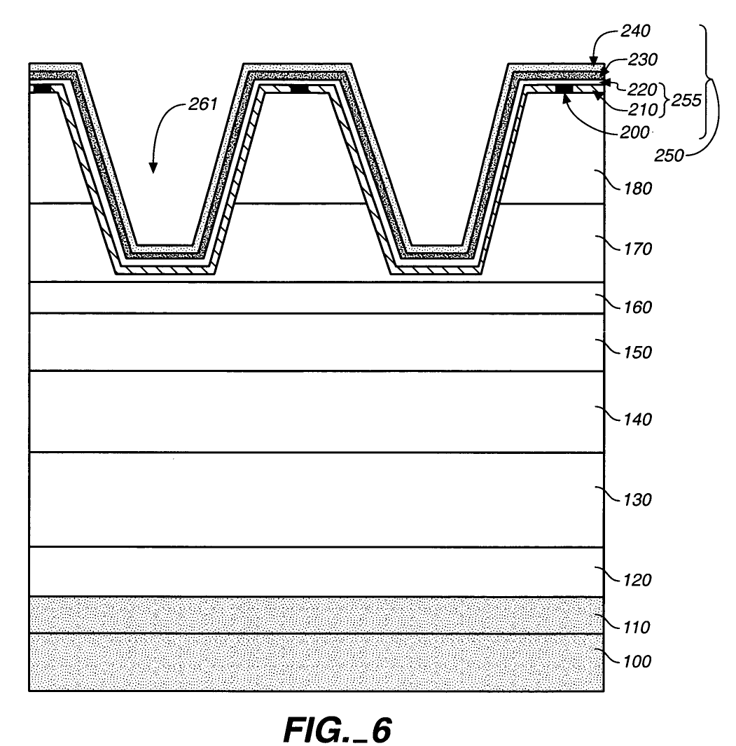

In one embodiment of the present invention, some recesses 261 are etched into the semiconductor thin film as illustrated in FIG. 6. The recesses typically penetrate into the window layer 180 and into the cladding layer 170 as well. In some cases, the recess may get very close to the active layer 160 or even penetrate into it. In addition to an increase in light extraction, these recesses have two others important functions: First, they ensure a strong bonding between the semiconductor structure and the new carrier resulted from the stress relaxation of soft filling material in the recesses; secondly, they also improve the heat dissipation capabilities of the device when filled with a high thermal conductivity material.

Light generated from the active layer 160 excites many electromagnetic modes propagating inside the LED chip. Some are confined between the active layer 160 and the cladding layers/waveguide layers 170. Some propagates inside the window layer 180 of the die. Among those optical modes, some will reach the interface of the window layer 180 and surrounding medium, i.e. air, and escape the device, but most of them will not. Therefore a large amount of the light emitted in the active layer 160 is trapped inside the window layer before being recycled or absorbed. It is common knowledge that the recombination length in AlInGaP materials is around 30 μm. Therefore a solution has to be found to allow the light carried by these modes to quickly escape from the device before being absorbed or recycled within an order of the recombination length. One solution is to perturb these modes by creating corrugated optical interfaces such as grooves into light propagation medium that will change their propagation and allow the light carried by these modes to exit the device.

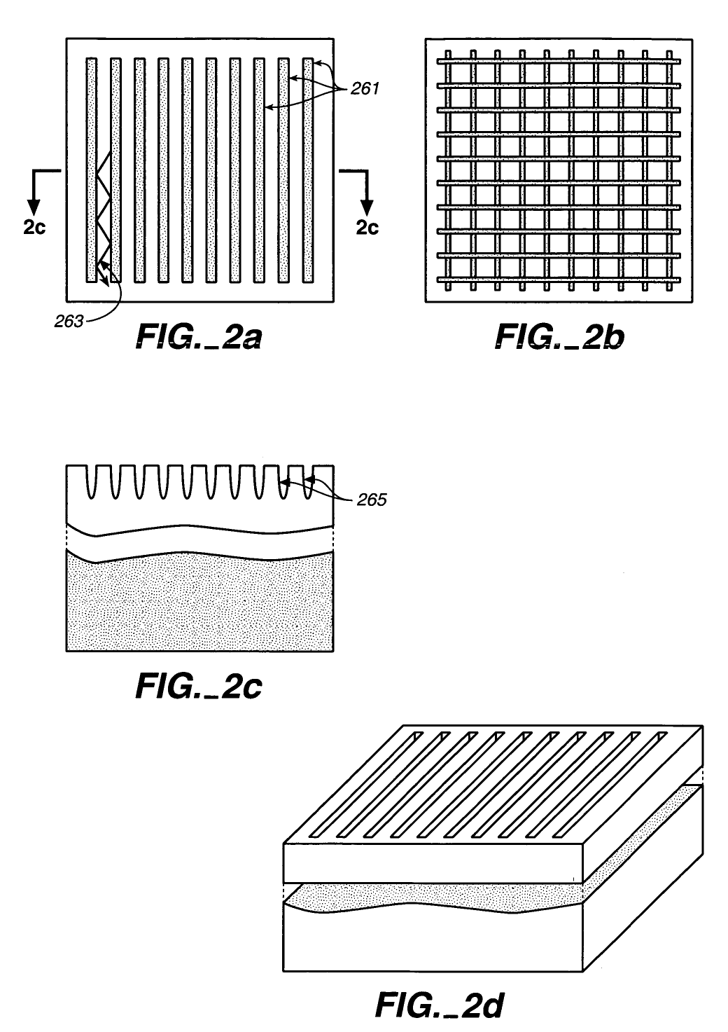

In one embodiment of the present invention, the recess features (indicated by 265 in FIGS. 2c and 261 in FIG. 2-a) are etched into the thin semiconductor film following an appropriate crystal orientation of the window layer 180. The thickness of the window layer needs to be enough to ensure not only good current spreading but also adequate space for creating recesses. The thickness of one micrometer to tens of micrometers may be used. Consequently, the etched surface of the recess will be smooth owing to crystalline structure. The recess surfaces are thereafter coated with a reflective metal mirror, whose reflectivity strongly depends on the surface smoothness. The reflective corrugated mirrors strongly enhance light extraction.

As illustrated in FIG. 2-a, the recess features 261 may be a dense array of parallel lines. These lines are uniformly distributed across the surface of the chip. As illustrated in FIG. 2-c, which is a cross-sectional view of FIG. 2-a, the lines preferably form V-grooves inside the semiconductor thin film. The width of the lines may vary from 1 to 30 μm. In FIG. 2-c the depth of the recess lines 265 are typically in the order of hundreds of nanometers to hundreds of micrometers. Controlling the depth of the recesses is useful and achieved by ensuring a high etching selectivity between the different layers of the light emitting structure or by precisely controlling the etching parameters. For example, a high etching selectivity can be obtained between the window layer 180 such as GaP, AlGaAs and the like and the waveguide and/or cladding layer 170 such as AlAs, AlInGaP, and the like by using wet etching solution like the mixture of Potassium Dichromate, Acetic and Hydrogen Bromide and dry etching gas like Chlorine plasma as illustrated in FIG. 6. The recesses preferably penetrate into the window layer 180 and the p-cladding layer 170 as well. In another embodiment, the recesses may penetrate the active layer 160 and even enter the n-cladding layer 150, but this deep penetration many have drawback of creating current leakage passage, which adversely affects device reliability. FIG. 2-d shows a 3D-perspective view of the device after etching. However some light still propagates between the parallel lines without being extracted as indicated by 263 in FIG. 2-a.

Therefore, in another embodiment of the present invention, two perpendicular sets of recess lines are formed as illustrated in FIG. 2-b. Light can neither propagate into the p-cladding layer or the window layer nor exit the LED chip without hitting the surface of the recess or the top surface. Therefore, light will be extracted in a much more restricted region and therefore more efficiently.

These recesses have mechanical and optical merits. First, mechanically they ensure a strong bonding between the semiconductor structure and the new carrier and better heat dissipation due to the metal filling in the recesses. Optically they contribute to the light extraction enhancement. To do so, a highly reflective mirror is formed over the surfaces of the recesses.

Methods to manufacture metallic mirrors and composite mirrors (combination of a dielectric layer and a highly reflective metal) on the surface of light emitting diodes have already been published in “T. Gessmann, E. Fred Schubert, J Graff, K Streubel Light-Emitting Diodes: Research, Manufacturing, and Applications VII, Proc. SPIE, Vol. 4996, p 26”.

The following paragraphs detail the formation of ohmic contacts and highly reflective composite mirrors in embodiments of the present invention.

As illustrated in FIG. 6 a p-contact metal 200 is deposited locally on the surface by e-Beam evaporation or sputtering with a typical masking process. For example, the metal can be either a combination of Pt, Ti and Au, which exhibit a very high absorption, or preferably a highly reflective metal such as AuZn, AuBe or a semi-transparent metal such as thin NiO/Au and thin Pd/Pt layers for gallium nitride-based devices.

The annealing temperature and time required to form a low resistance p-ohmic contact ranges from 350° C. to 500° C. and for few seconds to a couple of minutes, respectively. Once the ohmic contact is formed, the reflectivity of the ohmic contact metal will be normally reduced due to alloying of contact metal and can drop as much as 50%. Therefore it is useful to choose the right annealing conditions for minimizing the reflectivity drop without adversely affecting the electrical properties of the device.

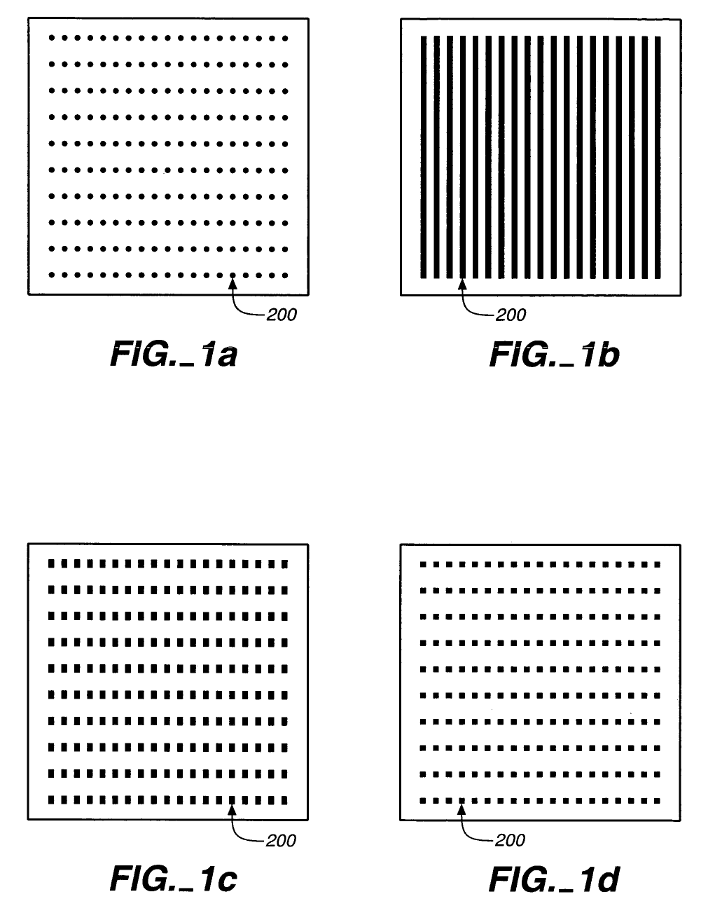

To further reduce the absorption due to the contact metal, the ohmic contact metal is generated only on localized areas of the semiconductor film to reduce contact area. As explained above, the ohmic contact area is absorbing light emitted in the active layer because of alloying of the contact metal after annealing. The alloy increases the absorption and reduces the reflectivity. Highly reflective metals such as AuBe or AuZn alloys for AlInGaP structures or NiO/Au or thin Pd/Pt layers for Gallium-nitride based structure are typically used. The metal contacts 200 in FIG. 1 are evaporated on the surface typically covering between 0.5% and 5% of the semiconductor die.

As illustrated in FIG. 1, these isolated metal islands can take various shapes such as dots (FIG. 1-a), lines (FIG. 1-b), ovals (FIG. 1-c) or squares (FIG. 1-d). On top of these contacts a “composite mirror” 255 is formed, in which consists of the depositions of one transparent dielectric layer 210 and thereafter a highly reflective metal layer 220 as shown in FIG. 6. The p-metal contacts 200 are connected to the reflective metal 220 via openings through the dielectric layer 210.

Several different metals exhibit a high reflectivity in the visible spectrum and the highly reflective metal layer 220 can be any or a combination of the following: Al, Ag, Au or etc. These metals have a reflectivity higher than 80% in wavelength range of 420 nm-650 nm. The deposition of a dielectric layer 210 between the metal layer 220 and the semiconductor layer 180 and 170 increases the overall reflectivity of the mirror. It also ensures the stability and the absence of diffusion during the bonding process, during the subsequent annealing of the n-metal contact and during the operation of the device. For example the dielectric layer 210 can be any of the oxides or nitrides of Si, Ta, Nb, Al, In, Mg, Sn. The thickness of the dielectric layer 210 is optimized within the composite mirror 255 for the best reflectivity. In addition to the optical benefit of the transparent dielectric layer: formation of a Fabry-Perot type of cavity, the presence of this layer 210 prevents any reaction and inter-diffusion process to take place between the reflective layer 220 and the semiconductor top layer 180. Therefore the reflectivity of the metal mirror is preserved.

While the invention has been described by reference embodiments, it will be understood that modification changes may be made without departing from the scope of the invention, which is to be defined only by the appended claims or their equivalents. For example it will be understood that the shaping of the semiconductor thin film can be applied to different types of structures and that the etching of the recesses can be made into a single thin p-layer such as p-GaN or a thick layer such GaP.

Bonding Layers Formation

After formation of the ohmic contact and reflective mirror, several more layers needs to be formed on the semiconductor wafer surface to ensure a high manufacturing yield before bonding the carrier wafer onto the semiconductor wafer.

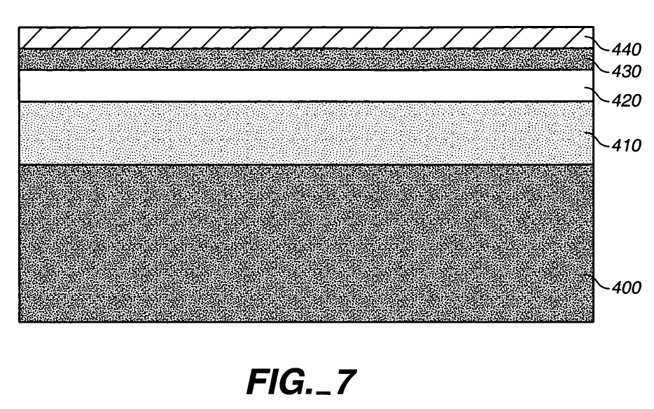

As illustrated in FIG. 6, the preparation of the semiconductor film includes:
1. The step of forming an ohmic contact layer 200 on the surface of the semiconductor last grown layer 180 to create good electron injection conditions.
2. The step of forming recesses indicated by 261 in FIG. 6 such as dense lines shown in FIG. 2-a into the semiconductor film to enhance light extraction and to increase bonding strength as described above.
3. The step of forming a composite reflective mirror 210 and 220 as described above.
4. The step of forming a barrier layer 230, which prevents the inter-diffusion of the bonding layer 440 in FIG. 7 and the reflective metal layer 220 in the composite mirror. The barrier layer 230 can be typically Cr, Ti/W or Nb. It has been proven for this specific application and the specific range of temperature considered, Niobium (Nb) is an excellent choice that has all the required properties in terms of stability and adhesion and will stop inter-diffusion between the composite mirror and the bonding layer 440.
5. The step of forming a wetting layer 240 includes the deposition of a layer such as Au or Cu or Ni that will enhance the adhesion of the bonding layer 440 to the barrier layer 230.
6. The step of forming a bonding layer 440 is important to the success of the bonding process. In the present invention, the bonding layer 440 can be formed either in the carrier wafer or on the top of the wetting layer 240 in FIG. 6 of the semiconductor wafer. E-Beam Evaporation, sputtering or electroplating can be used for the deposition of the bonding layer 440. Electroplating is a cost-effective method that can generate thickness of metal layer ranging from tens of nanometers to hundreds of microns.
7. The step of forming a filling layer is described above. This layer has a high thermal conductivity and is formed inside the recesses of the semiconductor structure. This layer is formed preferably after the formation of the wetting layer 240 and prior to the formation of the bonding layer 440. The purpose of this layer is to improve the heat dissipation capabilities of the device by replacing the semiconductor material etched away by a high thermal conductivity material. This material can be any of the following: Au, Ag, Cu, Sn, In, Pb, and Cu/W.
   Carrier Preparation

The original growth substrates on which III-V semiconductor layers are usually grown have a low thermal conductivity. The thermal conductivities of GaAs substrate and sapphire substrate are 50 W/m° C. and 40 W/m° C., respectively. As illustrated in FIG. 7, the new carrier 400 for the thin film semiconductor film should have better heat dissipation characteristics than the original growth substrate. The bonding method presented in this document allows a wide range of choice for the new carrier. The following table lists some candidates for being a carrier:

| Material | CTE (ppm/° C.) | Thermal conductivity (W/m° C.) |
|---|---|---|
| GaAs | 6.5 | 50 |
| Sapphire | 5.0-5.6 | 40 |
| Si | 4.1 | 150 |
| Copper | 17 | 400 |
| Cu—Mo—Cu | 6.0 | 182 |
| AlSiC | 6-16 | 170-220 |

The new carrier is selected depending on the requirements for intended applications. It can be any of the following materials: Si, GaAs, Cu, Al, SiC, AlSiC, Cu/M (where M can be Mo, W, or C), Graphite, AlN, Al2O3, Quartz, Cu/Mo/Cu and the like. For example, the CTE of Silicon significantly mismatches with that of GaAs-based epitaxial material, but Silicon is low cost and has excellent surface quality and mechanical strength. The present invention of “clamping effect” as described herein is able to reduce and manage the bonding stress. For the other example, the CTE of Cu—Mo—Cu composite metal perfectly matches to that of GaAs-based and GaN-based LED materials, but is more expensive.

As illustrated in FIG. 7, the preparation of the wafer carrier 400 includes:
1. The step of forming a contact layer 410 on the surface of the carrier 400 to generate good ohmic properties and good bonding properties. Sufficient thickness of the contact layer 410 is applied to cover surface imperfection of the carrier.
2. The step of forming a barrier layer 420 which will inhibit the inter-diffusion between the carrier 400 and the bonding layer 440 in order to avoid forming alloy in the bonding layer, which will weaken the bonding strength. The barrier layer 420 can be any or combination of Cr, Ti/W, Nb or other metals. It has been proven for the present invention that Niobium (Nb) is an excellent choice, which presents all the required properties in terms of stability and adhesion. Niobium layer will stop the reaction between the carrier 400 and the bonding layer 440.
3. The step of forming a wetting layer 430 includes the deposition of a layer typically Au or Cu or Ni that improves the adhesion of the bonding layer 440 to the barrier layer 420. This additional layer progressively reacts with the bonding layer 440 and enhances the bonding morphology and reliability.
4. The step of forming a bonding layer 440 is important to the success of the bonding process. E-Beam Evaporation, thermal evaporation, co-deposition, sputtering, or electroplating are suitable methods for the formation of the bonding layer 440. Electroplating is cost effective method that can generate a desirable bonding layer thickness of the order of hundreds of nanometers to hundreds of micrometers for a durable bonding in the present invention, but suffers from morphology non-uniformities that the other methods do not reveal. The bonding layer 440 can be formed either on the carrier or on the semiconductor film or both. The materials for the bonding layer 440 preferably have low melting temperature and low Young's Modulus (i.e. ductile) such as Tin, Lead, Indium, Sn/Au alloy, etc.
   Bonding Process

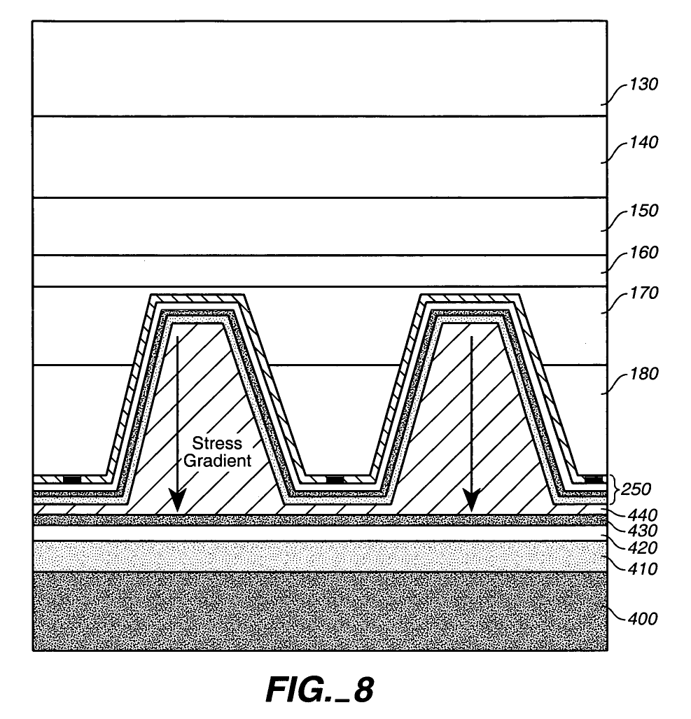

In the present invention the bonding process is carried out at such a temperature that the bonding layer 440 reaches a liquid state. During the bonding phase, a certain amount of bonding material 440 called solder is squeezed into the recesses 261 in FIG. 6 of the semiconductor and therefore creates a “clamping effect” on the wafer when the solder layer 440 is solidified. Therefore the bonding strength is significantly improved. FIG. 8 shows the full structure after bonding of the carrier (FIG. 7) and semiconductor wafer (FIG. 6). Preferably a melting temperature of the solder material 440 is between 100° C. and 350° C.

In one embodiment of the present invention, a clamping effect is generated on the semiconductor LED film itself due to the higher CTE of the bonding layer 440. The CTE of the semiconductor is typically in the range of 4 to 6 ppm/° C. while the bonding layer 440 has a CTE ranging from 20 to 30 ppm/° C. FIG. 8 shows that stress due to the CTE mismatch gradually decreases upwards the recess from layer 430 to layers 170. During the cooling stage, the solder 440 “shrinks” much more than the semiconductor film and at the same time creates a clamping effect on the semiconductor film. The strength of the bonding is strongly improved as well as the yield of the process and the reliability of the device.

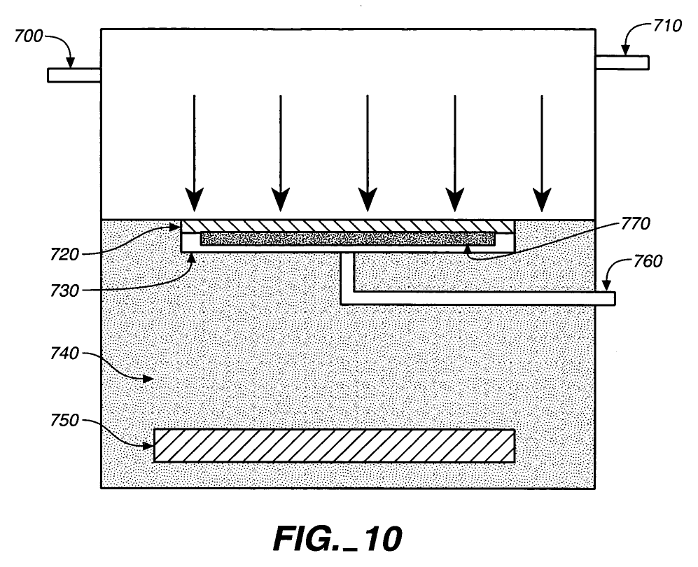

As illustrated in FIG. 10, the carrier and semiconductor LED wafer assembly 770 is placed in the cavity 730 for bonding or annealing. The apparatus possesses a gas inlet 700 and a gas outlet 710 to pressurize the chamber. A heater 750 is built inside a bulk metal base 740 that has a high thermal conductivity for obtaining a uniform temperature across the wafer assembly 770. The cavity is connected to a vacuum port 760. A flexible film 720 made of a high-temperature sustainable film such as polyimide, Al, Cu, Ni or stainless steel is used as the seal over the wafer assembly 770 to maintain the vacuum. A gas pressure is applied over the wafer assembly 770 while the temperature is raised to reach temperature for bonding or annealing of the N metal to generate ohmic contact. For bonding of LED wafer and carrier using a soft solder such as Sn, the typical bonding temperature ranges from 250 to 400° C., and pressure for the bonding ranges from 14 psi to 500 psi. The thickness of the film 720 is chosen to conform to the contour of the wafer surface. 0.1-30 mils of polyimide or aluminum film can be used for the application due to the high temperature stability and non-sticking property of the film against the LED surface. Typical temperature for ohmic contact annealing ranges from 300 to 500° C. The flexible film press against the semiconductor epitaxial film and prevent it from moving during bonding process due to re-melting and solidification of the bonding layer 440.

The use of a fluid pressure (gas pressure) ensures a uniform distribution of the pressure across the entire wafer surface 770 so that the pressure applied is isostatic. The flexible film transfers the pressure uniformly from the chamber to the surface of the wafer. There are no wedge issues that are typical of the uni-directional hard-press tools. Therefore, the bonding is much more uniform and exhibit a much higher yield.

Substrate Removal

The selective removal of the substrate is then carried out. The removal process includes a combination of these methods: Mechanical grinding/polishing or chemical etching or laser dissociation.

It is understood that the new carrier might be highly reactive especially in the case of chemical etching. The removal process has to selectively remove the original substrate, e.g. 100 in FIG. 6 without damaging the semiconductor thin film and the new carrier. Therefore the presence of a protective layer such as stop layer 120 in FIG. 6 is recommended and even the presence of a protective layer on the new carrier. Typically, NH₄OH solution is used to remove GaAs substrate, and laser lift-off for the Sapphire substrate removal.

N-Metal and its Absorption Minimization

One aspect of this invention is to propose a method to increase the extraction efficiency by reducing absorption due to the metal electrodes of the light emitting diode.

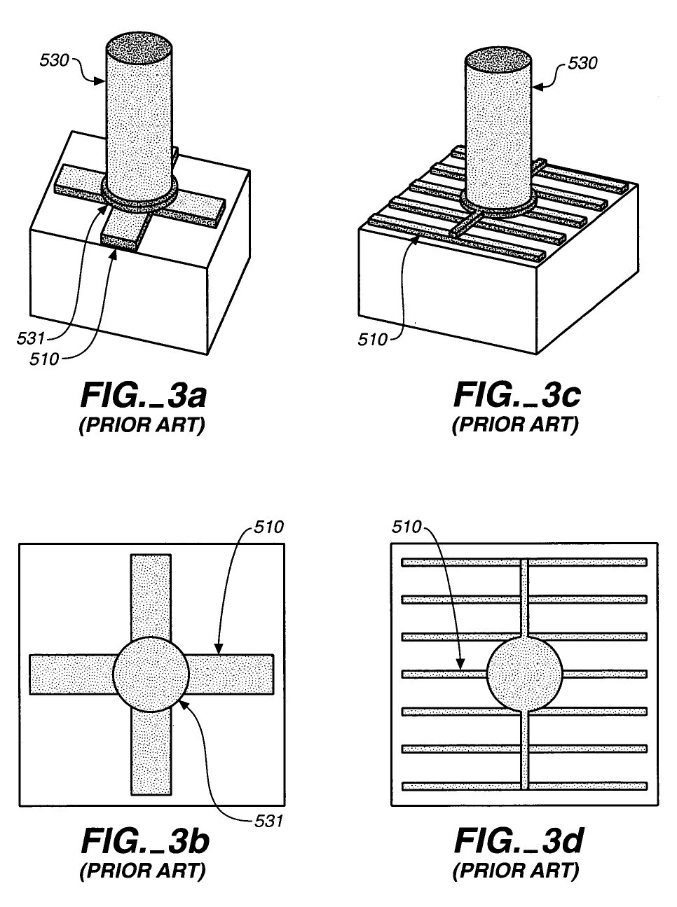

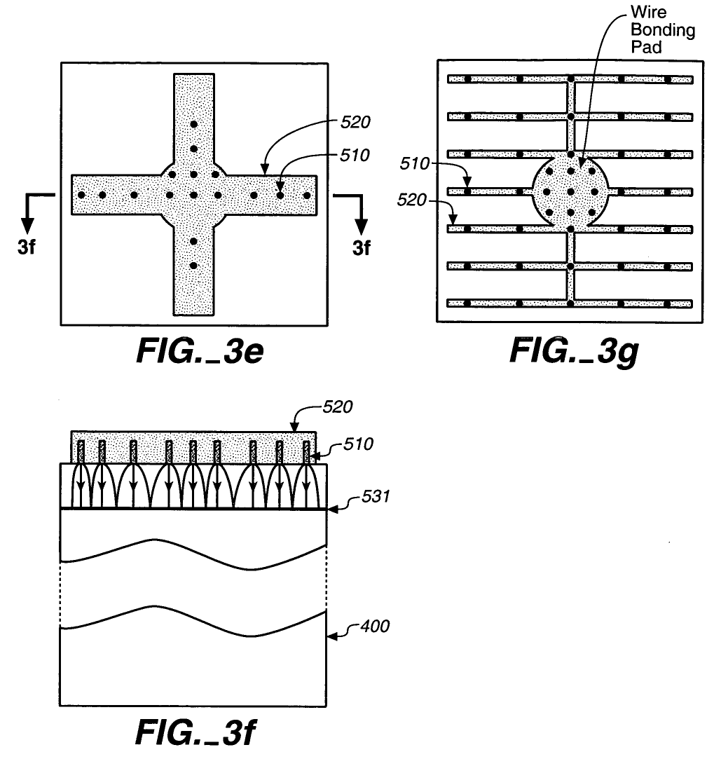

To operate a light-emitting device, an electrode 510 in FIGS. 3a-3d has to be formed on its upper side. Once integrated into a packaging, this electrode will be connected to an electrical power source via a wire 530 in FIGS. 3a and 3c. This electrode ensures low resistance electron injection (low-resistance ohmic contact), provides uniform current spreading across the surface of the device and ensures a strong mechanical bonding of the wire to the device.

The wire bonding process requires a metal pad 531 in FIGS. 3a and 3b that typically ranges from 80 μm to 120 μm in diameter. Standard LED chips are usually square dies with surface areas between 250 μm*250 μm and 350 μm*350 μm ranges. It means that the metal pad alone covers between 10% and 20% of the total surface area of the chip. For III-V phosphide based materials, a combination of Ge, Au and Ni is typically deposited on the n-side and annealed to create a low-resistance ohmic contact between the metal and the semiconductor. For AlInGaN-based LEDs, a combination of Ti, Pt, Au, Al, Mo, Pd, and Ru is used to form a good N-type ohmic contact. FIGS. 3a-3d illustrate these conventional configurations and feature a wire 530 typically 50 μm and 100 μm in diameter used in wire bonding process.

The imaginary part of the refractive index of Germanium has a very high value: k_{Ge}=5.5 (at 650 nm). Few nanometers of Ge will then completely absorb any light reaching the metal pad. However, Ge alloys can withstand a high current density. Consequently their size can be significantly reduced and still keep good ohmic properties.

Therefore, in one embodiment of the present of invention, a multitude of isolated metal islands 510 in FIGS. 3e and 3g forming good ohmic contact to the epitaxial semiconductor layer are spread over its surface. It should be noted the ohmic contact is either P-type or N-type dependent on doping types of the semiconductor layer beneath the isolated metal islands 510. Thereafter an electrically conductive layer 520 is deposited on the surface of the semiconductor to connect all metal islands 510 and to form a continuous metal network that ensures good injection conditions and good current spreading. The interface between the conductive layer 520 and the semiconductor layer is non-ohmic and appears high current resistance. The external current through bonding pad and conductive network layer 520 is evenly distributed to the multitude of isolated metal islands 510 and then flow downward into the active layer 531 in FIG. 3f, which is a cross-sectional view of the structure in FIG. 3e. Therefore the current is uniform across the active layer 531 to efficiently generate radiation within. The material of the conductive layer 520 can be either highly light reflective or transparent against the operational LED wavelength. In the case where a high reflective material such as Al, Au, Ag, Cu and etc is chosen for the conductive layer 520, light emitting from the active layer 531 is bounced back into the LED structure by the conductive layer 520. It will be either reflected at the composite mirror surface (FIG. 6) and escaped or reabsorbed by the active layer. Photons reabsorbed by the active layer can be re-emitted or so called recycled. Namely, light reflected by the reflective metal layer 520 is reused. In case of transparent and conductive materials such as Indium Tin oxide (ITO) are chosen, light will directly exit through it.

The isolated islands can take many shapes such as dots, squares, ovals or lines. The surface area covered ranges between 0.2% and 2% as opposed to 10% to 20% in the prior arts. The configuration with dots is illustrated in FIGS. 3e and 3g. The highly reflective metal 520 can be any of the following: Au, Ag or Al. In one implementation, the making of the isolated metal islands 510 and conductive network 520 structures is preferably performed by optical lithography techniques.

N-Side or P-Side Shaping

The light extraction efficiency of an LED depends on the amount of light that exit the device from each facet of the device. Five of these six facets of a LED die have an interface with the surrounding medium, which is typically air (refractive index nₐᵢᵣ=1) or a capsule (refractive index 1.4<n_{enc}<2). The shaping of these five facets significantly improves the extraction efficiency of LEDs.

One embodiment of the present invention proposes a method of shaping a light emitting diode surface so that each facet does not feature a critical angle. Only a small portion of light escapes from the device because of large index difference between the semiconductor material and the surrounding medium.

Considering the active layer of an AlInGaP-type LED as an isotropic light emitter, there is only 17% of light located within the escaped cone, which exit t a LED chip surface. The disruption of the surface aims at extracting light outside an escaped cone by offering the photons alternative paths for extraction. Given the isotropic nature of light emission by an LED, the increase of the surface area statistically increases the amount of light extracted form the device.

There are several ways to disrupt the surface: for example natural lithography described in “Schnitzer and al, App. Phys. Lett., Vol 74, No 16, pp. 2174-2176”. “However the making of sub-wavelength features requires high cost manufacturing tools or special nano-particles masking methods such as colloidal silica. The making of micron size features uses standard semiconductor process recipes and is therefore cost-effective.

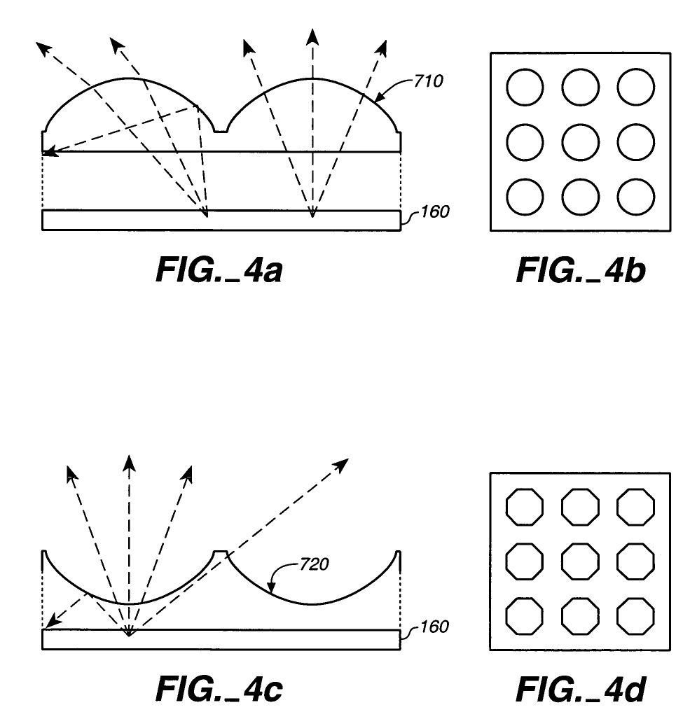

In one embodiment of the present invention, the surface is disrupted so that a higher percentage of the light emitted inside the device, escapes. As illustrated in FIG. 4-b and FIG. 4-c, a regular, spatially periodic, pattern is etched on the surface of the semiconductor, as dense as possible with sidewalls almost connecting to each other.

Each pattern will preferably have a lens shape, either convex 710 in FIG. 4-a or concave 720 in FIG. 4-c. As illustrated in FIG. 4a, the convex lens will be shaped so that the center of curvature of the lens surface lies in the plane of the active layer 160. Light isotropically emitted from the center of curvature of the lens will hit the surface at a 90° angle. Therefore, the angle of incidence will be smaller than the critical angle and light will be extracted from the device. If light is emitted from a portion of the active layer that is not the center of curvature of the lens surface, it will not hit the lens surface with a 90° angle of incidence and thus might not be extracted. However, the presence of lenses on the surface automatically increases the surface area and therefore increases the probability for isotropically emitted photons to escape from the device.

FIG. 4c illustrates the effect of concave microlenses 720 formed on the surface of the light-emitting device. The concave microlenses are shaped so that if light generated at the focal point of the lens is emitted towards the corresponding lens with a small angle then it will be extracted. If light is emitted with a larger inclination, then it may be extracted by neighboring lens.

For example, for GaP-type LED chip and air medium, the lens is formed so that light emitted from the focal point of a lens within a 17° half-angle cone hits the corresponding lens and is extracted. Light emitted with an inclination between 17° and 51° hits the neighboring lenses, the neighboring lens has a surface that has an escape cone corresponding to the inclination 17° to 51°. Additionally, the presence of concave lenses on the surface automatically increases the surface area and therefore increases the probability for isotropically emitted photons to escape from the device. Manufacturing smooth rounded features is difficult and not cost-effective. In lieu of smooth lens surface, hexagon or cone shape lens surface is fabricated without substantially sacrificing the extraction effectiveness for the sake of low cost.

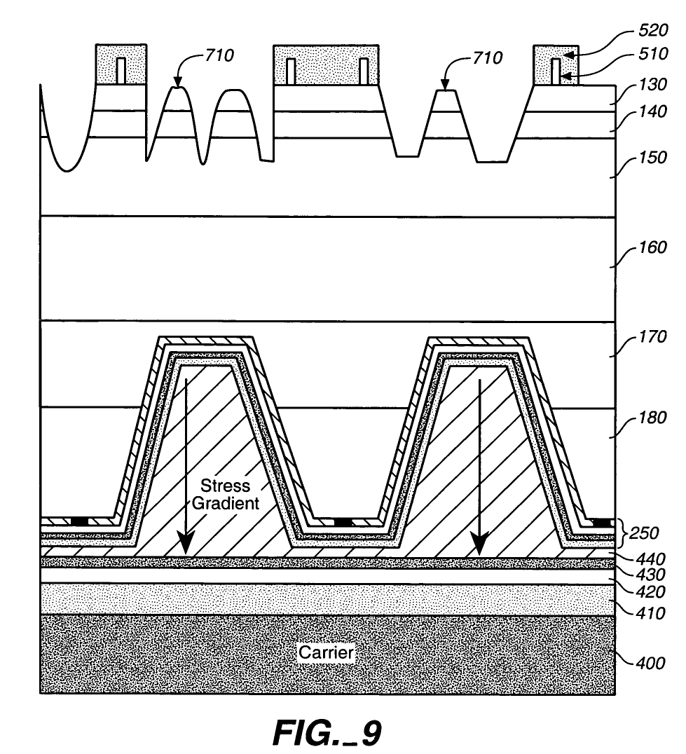

FIG. 9 is a cross-sectional view of the device after bonding and formation of the metal contact electrode 510 and 520 and surface features 710. The lenses 710 etched on the surface of the light-emitting device cover the entire surface of the light-emitting device except the metal electrode. Their depth is tailored to ensure maximum efficiency. They preferably penetrate into the contact layer 130, the space layer 140 and the n-cladding/waveguide layer 150. They may also penetrate the active layer 160.

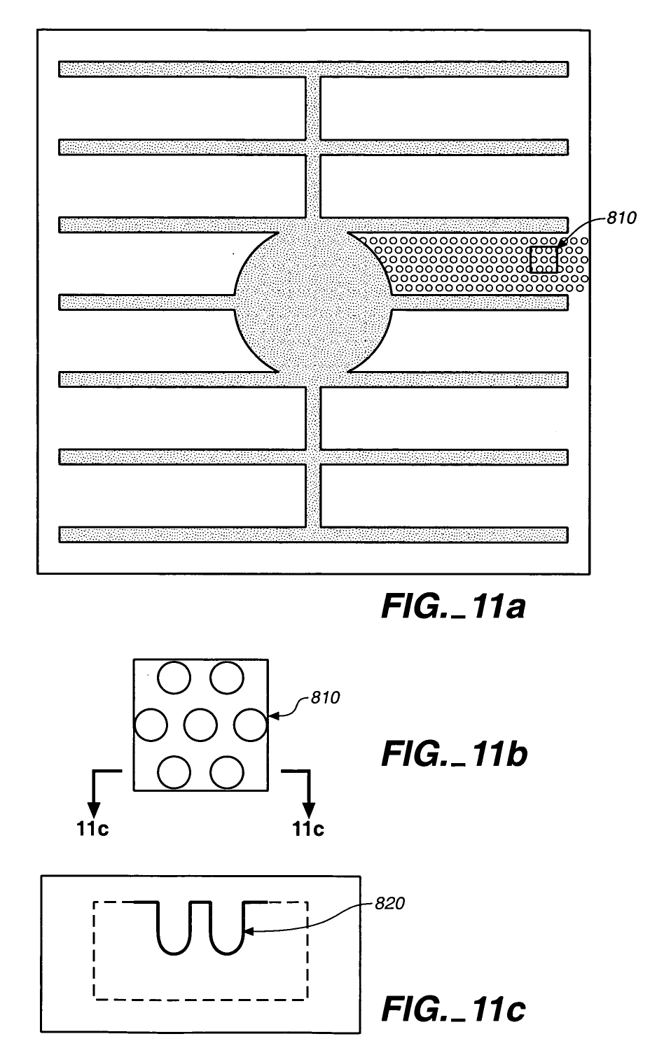

In another embodiment of the present invention, a regular periodic or quasi-periodic hole array 810 in FIG. 11-a forming a photonic band gap structure is inscribed on the top surface of LED chip. The shape of holes is preferably conic, as indicated by 820 in FIG. 11-c, to increase the light extraction efficiency. FIG. 11-b is a blow-up view of photonic band gap structure shown in FIG. 11-a. FIG. 11-b illustrates a tri-angular array of holes as an example. Light generated from the active layer excites many electromagnetic modes propagating inside the LED chip. The photonic band gap structure facilitates the extraction of the guided modes and leakage modes. The extraction is further enhanced by the high reflectivity of the composite mirror for optical rays in all incident angles in the p-side wafer bonding shown in FIG. 9. The high reflectivity for high-incident-angle rays reduces the dissipation of guided modes into the substrate such that the photonic band gap structure has more time to extract the modes before they are lost. The photonic band gap structure is mainly dependent on the lattice constant, i.e. distance between holes, and the size of holes. The lattice constant for the lowest order mode of the photonic band gap structure is a fraction of the wavelength and a multiple of times of wavelength for the high-order modes. For easy manufacturing and low production cost, high-order modes with lattice constant in the order of micrometers are selected in the visible and UV operation.

While the invention has been described above by reference to various embodiments, it will be understood that changes and modifications may be made without departing from the scope of the invention, which is to be defined only by the appended claims and their equivalent. All references referred to herein are incorporated by reference.

What is claimed is:

1. A light emitting apparatus comprising:
a semiconductor structure comprising a light emitting diode, said structure having recesses therein;
a carrier that has a thermal conductivity that is higher than that of the structure and/or a CTE where there is a substantial mismatch between CTE of the structure and that of said carrier; and
a stress-absorbing material attaching the structure to the carrier, said material substantially filling said recesses.

2. The apparatus of claim 1, wherein the CTE of the carrier is different by at least 10% from that of the structure, said material reducing stress between the structure and the carrier when they are attached together by the material.

3. The apparatus of claim 2, wherein the stress-absorbing material includes solder.

4. The apparatus of claim 3, wherein a melting temperature of the solder is between 100° C. and 350° C.

5. The apparatus of claim 2, wherein when the structure and the carrier are attached by heating the stress-absorbing material between the structure and the carrier until it melts and subsequently cooling the material, a clamping force is asserted between the structure and the carrier.

6. The apparatus of claim 5, wherein the stress-absorbing material includes Sn, In and/or Pb and their respective alloys.

7. The apparatus of claim 1, said stress-absorbing material comprising at least one of the following group to enhance heat dissipation: Au, Ag, Cu, W, Sn, In, Pb.

8. The apparatus of claim 1, said carrier comprising one or more of the following material: Si, GaAs, Cu, Al, SiC, AlSiC, Cu/M (where M is Mo or W), Graphite, AlN, Al₂O₃, Cu/Mo/Cu.

9. The apparatus of claim 1, said structure comprising an active layer, a p-cladding layer and/or waveguide layer, a n-cladding layer, a window layer, a contact layer, a etching stop layer, a buffer layer and a space layer.

10. The apparatus of claim 1, said structure comprising a light reflective layer on a surface of the structure at the recesses.

11. The apparatus of claim 10, said light reflective layer comprising a metal material.

12. The apparatus of claim 11, said structure further comprising a dielectric layer between the reflective layer and a semiconductive material in the structure.

13. The apparatus of claim 12, said dielectric layer comprising oxide(s) or nitride(s) of any one or more of the following: Si, Nb, Ta, Al, In, Mg, Sn.

14. The apparatus of claim 11, said light reflective layer comprising any one or more of the following: Au, Ag, Al.

15. The apparatus of claim 11, further comprising a barrier layer between the reflective layer and the carrier, said barrier layer preventing diffusion of the stress-absorbing material into the semiconductor structure and damage to the light reflective layer when the structure is attached to the carrier.

16. The apparatus of claim 15, wherein said barrier layer comprises Nb.

17. The apparatus of claim 15, further comprising a wetting layer which facilitates uniform adhesion of the barrier layer with the stress-absorbing material.

18. The apparatus of claim 10, said structure further comprising convex and/or concave microlenses on a surface of the structure opposite to the reflective layer, so that light reflected by the reflective layer has a greater chance of escaping from the structure through the microlenses.

19. The apparatus of claim 18, said structure comprising an active layer, wherein said microlenses have focal planes or foci in the active layer of the structure.

20. The apparatus of claim 1, said recesses being in the form of a one or more arrays of trenches.

21. The apparatus of claim 1, said recesses being in the form of two arrays of trenches arranged in directions transverse to each other.

22. The apparatus of claim 1, said structure further comprising a photonic crystal pattern.

23. A light emitting apparatus comprising:
a semiconductor structure comprising a light emitting diode; and
an electrically conductive network for applying a current to the structure to cause the diode to emit light, said network comprising:
an array of metal contacts wherein each of at least some of the contacts is not in contact with any other contact in the array, and wherein the contacts form ohmic contacts with the semiconductor structure; and
an electrically conductive material connecting the contacts, said material being light reflective or substantially transparent with respect to light emitted by the diode.

24. The apparatus of claim 23, wherein said electrically conductive material is in contact with the semiconductor structure, and wherein the contact between the semiconductor structure and the material is substantially non-ohmic.

25. The apparatus of claim 23, said metal contacts comprising Ni, Ge, Pd, Ti, Pt and/or Au.

26. The apparatus of claim 23, said metal contacts comprising an alloy comprising a Ge—Au, Pd, Al, Mo, Ru, Ge—Au—Ni, Pt or NiO/Au based alloy.

27. The apparatus of claim 23, said electrically conductive material comprising Au, Ag, Al or ITO.

28. A method for making a light emitting apparatus comprising:
providing a semiconductor structure comprising a light emitting diode, said structure having recesses therein; and
attaching to the structure a carrier having a thermal conductivity that is higher than that of the structure and/or a CTE where there is a substantial mismatch between CTE of the structure and that of said carrier by means of a stress-absorbing material so that said material substantially fills said recesses.

29. The method of claim 28, wherein the CTE of the carrier is different by at least 10% from that of the structure, so that said material reduces stress between the structure and the carrier when they are attached together by the material.

30. The method of claim 29, said attaching comprising:
placing the material in solid form between the structure and the carrier and heating the material until it melts and enters the recesses; and
cooling the material.

31. The method of claim 30, said carrier having a CTE that is different from that of the structure by at least 10% so that stress caused by different amounts of contraction of the carrier and the structure is reduced by movement of the material relative to the carrier and the structure when it is cooled.

32. The method of claim 31, wherein cooling of the material causes a clamping force to be asserted between the carrier and the structure.

33. The method of claim 28, said semiconductor structure comprising a crystalline current spreading layer, said providing comprising selectively etching said current spreading layer along one of its crystal orientation to form the recesses.

34. The method of claim 28, further comprising shielding the stress-absorbing material from the structure and/or the carrier by means of a barrier layer during the attaching.

35. The method of claim 34, wherein said barrier layer used in the shielding comprises Nb.

36. A method for attaching a semiconductor wafer to a carrier, comprising:
bringing the semiconductor wafer and the carrier into contact in a vacuum environment; and
applying uniform pressure and temperature to the semiconductor wafer and the carrier to create a strong and uniform bonding therebetween, wherein the pressure is unidirectional or isostatic.

37. The method of claim 36, wherein said pressure is applied by means of a hard press or through the use of a fluid.
